(19) United States
(12) Patent Application Publication
(10) Pub. No.: US 2004/0065256 A1
(43) Pub. Date: Apr. 8, 2004

(54) Systems and methods for improved gas delivery

(76) Inventors: Gi Youl Kim, San Jose, CA (US); Marbert G. Moore III, Liberty Hill, TX (US); Adrian Jansz, Fremont, CA (US); David K. Foote, San Jose, CA (US); Richard Lee Hendrickson, Brentwood, CA (US); Ken Doering, San Jose, CA (US)

Correspondence Address: CARR & FERRELL LLP, 2200 GENG ROAD, PALO ALTO, CA, 94303, US

(21) Appl. No.: 10/678,989

(22) Filed: Oct. 2, 2003

Related U.S. Application Data
(60) Provisional application No. 60/416,084, filed on Oct. 3, 2002.
(60) Provisional application No. 60/434,730, filed on Dec. 18, 2002.

(51) Int. Cl. C23C 16/00

(52) U.S. Cl. 118/715

(57) ABSTRACT

An improved chemical vapor deposition system including a lid having a channel configured for delivering reactive cleaning gas to the interior of the vapor deposition system. The lid including a cleaning gas distribution channel fluidly connected to a plurality of cleaning gas injection ports. The lid geometry is configured to generate desirable concentration gradients of reactive cleaning gas to the interior of a vapor deposition chamber. In some embodiments, the concentration gradient is selected to compensate for the temperature dependence of cleaning reactions. Methods of using the disclose system are disclosed.

### CROSS-REFERENCE TO RELATED APPLICATIONS

This application claims benefit of commonly owned U.S. Patent Application No. 60/416,084 entitled “Methods and apparatus for remote plasma cleaning with improved gas delivery lid assemblies,” filed Oct. 3, 2002, and of commonly owned U.S. Patent Application No. 60/434,730 entitled “Methods and apparatus for remote plasma cleaning with improved gas delivery lid assemblies,” filed Dec. 18, 2002. The above patent applications are incorporated herein by reference.

### BACKGROUND

1. Field of the Invention

This application is in the field of vapor deposition systems and more specifically in the field of semiconductor processing.

2. Prior Art

Tungsten silicide (WSiₓ) films are used to form electrode and interconnect material in semiconductor chip processing. These high purity films are generally produced in a single-wafer chemical vapor deposition (CVD) reactor using tungsten hexafluoride (WF₆), monosilane (MS, SiH₄), and dichlorosilane (DCS, SiH₂Cl₂) precursors under a tightly controlled environment.

In addition to producing desired WSiₓ films, the WSiₓ deposition process produces undesired films of precursor materials and reaction by products. Over time, these undesired films build up within the CVD chamber and may become a source of particle contamination if not removed regularly. CVD chambers used for producing WSiₓ films must, therefore, be cleaned regularly in order to provide a clean wafer process environment.

CVD chambers are currently cleaned using reactive cleaning gasses. In systems used to produce WSiₓ films the preferred reactive cleaning gasses include monatomic fluorine (F) or diatomic fluorine (F₂) species generated by dissociating NF₃ gas.

In one approach the NF₃ is disassociated within the CVD chamber using an RF plasma. This process is relatively inefficient and requires considerable time to generate a useful amount of reactive fluorine species. Furthermore, generating fluorine species within the CVD chamber also produces ions that result in sputtering of the chamber walls and other components within the CVD chamber. For example, this sputtering effect is known to reduce the lifetime of heaters typically found within the CVD chamber.

In another approach, reactive fluorine species are produced from NF₃ using a radio frequency (RF) plasma external to the CVD chamber. This remote plasma cleaning method may employ a commercially available external plasma source. In the external plasma source, NF₃ is disassociated to form the desired reactive fluorine species and nitrogen gases. These products are then delivered to the CVD chamber via the same plumbing used to deliver processing gasses such as WF₆ and SiH₄. The external process is more efficient than electron bombardment within the CVD chamber and components within the CVD chamber are not damaged through sputtering processes, as occurs when the plasma is formed within the CVD chamber.

However, there are several disadvantages to remote plasma cleaning. For example, the apparatus used for delivering processing gasses to the CVD chamber typically include complex flow paths that provide reactive fluorine species considerable opportunity to recombine before reaching the CVD chamber. In addition these apparatus are normally configured to provide uniform process gas distributions to a processing wafer within the chamber. This particular uniform gas distribution may not be desirable for cleaning.

In view of the above problems, and other disadvantages of the prior art, there is a need for improved systems and methods of cleaning CVD chambers.

### SUMMARY OF THE INVENTION

The invention includes systems and methods relating to an improved chemical vapor deposition (CVD) chamber. The improved CVD chamber is characterized by a chamber lid configured to deliver cleaning gasses, such as fluorine species, to the interior of the CVD chamber. The chamber lid has a distributed series of cleaning gas injection ports connect by a cleaning gas distribution channel. The gas injection ports are optionally oriented to control the distribution of cleaning gasses within the CVD chamber. The cleaning gas distribution channel and cleaning gas injection ports are separate from plumbing used to introduce processing gasses.

In a typical method of operation, reactive cleaning gasses, such as monatomic fluorine (F) and diatomic fluorine (F₂), are formed in an external plasma. These reactive fluorine species are allowed to flow into the gas distribution channel disposed within the CVD chamber lid. From the gas distribution channel the reactive fluorine species pass into interior of the CVD chamber through the gas injection ports. The concentrations of reactive fluorine species at various locations within the CVD chamber are optionally controlled by the orientation of the gas injection ports.

Various embodiment of the invention include a chemical vapor deposition system comprising a cleaning gas source configured to generate a reactive cleaning gas, and a chemical vapor deposition chamber including, a processing gas shower, a cleaning gas distribution channel separate from the processing gas shower, and a plurality of cleaning gas injection ports fluidly connected to the cleaning gas distribution channel and disposed to introduce the cleaning gas into an interior of the chemical vapor deposition chamber.

Various embodiment of the invention include a chemical vapor deposition chamber lid comprising a cleaning gas distribution channel disposed within a perimeter of the chemical vapor deposition chamber lid and configured to circulate a reactive cleaning gas, a plurality of cleaning gas injection ports configured to deliver the reactive cleaning gas from the cleaning gas distribution channel to an interior of a chemical vapor deposition chamber, the cleaning gas injection ports distributed around the chemical vapor deposition chamber lid and configured to deliver a greater concentration of the reactive cleaning gas to an upper region of the chemical vapor deposition chamber than to a lower region of the chemical vapor deposition chamber, and internal plumbing configured to supply the reactive cleaning gas to the cleaning gas distribution channel.

Various embodiments of the invention include a method of cleaning a chemical vapor deposition chamber, the method comprising generating a reactive cleaning gas, transporting the reactive cleaning gas to a cleaning gas distribution channel, the cleaning gas distribution channel being separate from any processing gas shower head, circulating the reactive cleaning gas around a perimeter of the lid, passing the reactive cleaning gas into the interior of the chemical vapor deposition chamber using a plurality of cleaning gas injection ports disposed in the lid, and generating a desired concentration gradient of the reactive cleaning gas in the chemical vapor deposition chamber.

Various embodiments of the invention include a chemical vapor deposition system comprising means for transporting a reactive cleaning gas to a cleaning gas distribution channel disposed in a lid of the chemical vapor deposition chamber, means for circulating the reactive cleaning gas around a perimeter of the lid, means for passing the reactive cleaning gas into the interior of the chemical vapor deposition chamber, and means for generating a desired concentration gradient of the reactive cleaning gas in the chemical vapor deposition chamber, the desired concentration gradient including a greater concentration near cooler elements within the chemical vapor deposition chamber than near warmer elements.

### BRIEF DESCRIPTION OF THE VARIOUS VIEWS OF THE DRAWING

FIG. 1 illustrates a CVD system, according to various embodiments of the invention;

FIG. 2 illustrates a cleaning gas injection ports disposed roughly perpendicular to CVD chamber walls, according to one embodiment of the invention;

FIG. 3 illustrates a cleaning gas injection ports disposed roughly parallel to CVD chamber walls, according to another embodiment of the invention; and

FIG. 4 illustrates an alternative embodiment of the CVD Chamber including a Chamber Collar.

### DETAILED DESCRIPTION OF THE INVENTION

The invention includes a lid for a CVD chamber having a gas introduction system for cleaning gas separate from any gas introduction system for processing gasses. The plumbing configured for introduction of reactive cleaning gas is configured to transport the reactive cleaning gas from a plasma source external to the CVD chamber to the interior of the CVD chamber. This plumbing includes a cleaning gas distribution channel and cleaning gas injection ports disposed within the lid of the CVD chamber. In typical embodiments, reactive fluorine species are used as the cleaning gas. The invention overcomes disadvantages of the prior art.

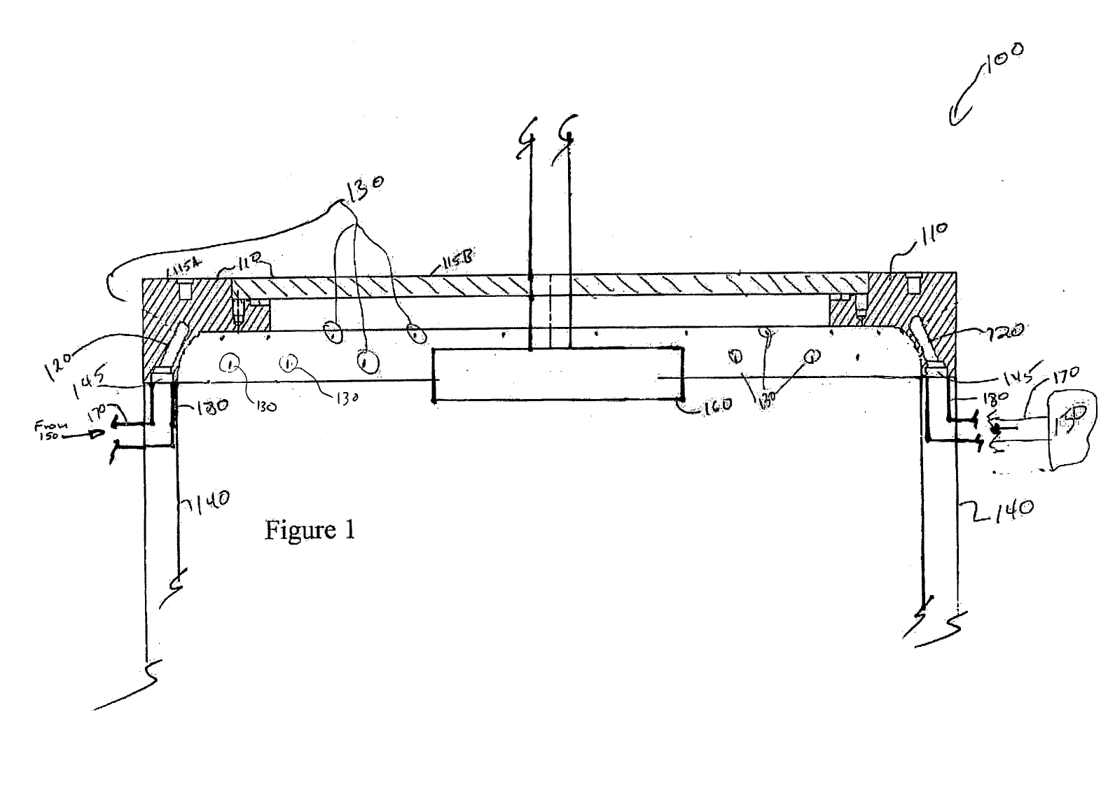

FIG. 1 illustrates a CVD system including a CVD Chamber generally designated 100. The view shown in FIG. 1 is a cross-section selected to show a CVD Chamber Lid 110 including at least one Cleaning Gas Distribution Channel 120 and more than one Cleaning Gas Injection Ports 130. CVD Chamber Lid 110 is attached to and typically supported by CVD Chamber Walls 140. Cleaning Gas Distribution Channel 120 optionally passes around the entire perimeter of CVD Chamber Lid 110 and includes one or more Channel Opening 145 for introduction of reactive cleaning gas from an External Cleaning Gas Source 150. CVD Chamber Lid 110 optionally includes more than one Lid Section 115A-115B. In the embodiment illustrated, Lid Section 115B is configured to support an optional Processing Gas Shower Head 160 for introduction of processing gasses, such as WF₆, into the interior of CVD Chamber 100.

In a typical embodiment, External Cleaning Gas Source 150 is configured to generate reactive fluorine species in a plasma. These reactive fluorine species flow through External Plumbing 170 and Internal Plumbing 180 to CVD Chamber Lid 110. Internal Plumbing 180 optionally passes through CVD Chamber Walls 140. Within CVD Chamber Lid 110 the reactive fluorine species circulate around the perimeter of CVD Chamber Lid 110 through Cleaning Gas Distribution Channel 120 and pass into the interior of CVD Chamber 100 through Cleaning Gas Injection Ports 130. Cleaning Gas Injection Ports 130 are dispersed along the perimeter such that a desired distribution of reactive fluorine species is achieved.

Cleaning Gas Injection Ports 130 are optionally disposed at more than one angle relative to CVD Chamber Walls 140 (or relative to an edge of CVD Chamber Lid 110) in order to achieve a desired distribution of reactive cleaning gas concentration that varies from the upper part of CVD Chamber 100 (where CVD Chamber Lid 110 is located) to the lower part of CVD Chamber 100 (toward the lower part of the cross-section shown in FIG. 1). As discussed further herein, in some embodiments, the Cleaning Gas Injection Ports 130 are configured such that there is a higher concentration of reactive cleaning gas directed near cooler parts of CVD Chamber 100 than near warmer parts of CVD Chamber 100.

Internal Plumbing 180 is optionally configured to minimize bends and turns so as to minimize opportunity for reactive fluorine species to undergo deactivating collisions with walls. For example, in some embodiments, External Plumbing 170 is coupled directly to CVD Chamber Lid 110 and Internal Plumbing 180 includes of a straight passage from the coupling point to Cleaning Gas Distribution Channel 120. While FIG. 1 depicts two instances of Channel Opening 145 within CVD Chamber Lid 110 and two instance of Internal Plumbing 180 within CVD Chamber Walls 140, it is envisioned that one, three, or more fluid paths between External Cleaning Gas Source 150 and Cleaning Gas Distribution Channel 120 may be employed.

Cleaning Gas Distribution Channel 120 may include a relatively large cross-section relative to the cross-section of Cleaning Gas Injection Ports 130. In some embodiments, the cross-section of Cleaning Gas Distribution Channel 120 is 10 or more times greater than the cross-section of Cleaning Gas Injection Ports 130. In other embodiments, the cross-section of Cleaning Gas Distribution Channel 120 is over 100 times greater. The larger cross-section allows gas to distribute evenly along Cleaning Gas Distribution Channel 120 and thus provides an even distribution of gas pressure at the entrance to Cleaning Gas Injection Ports 130. The even distribution of gas pressure helps assure a desired distribution of reactive cleaning glass within the interior of CVD Chamber 100. In addition, as discussed further herein, the relatively large volume of Cleaning Gas Distribution Channel 120 may serve as a buffer volume that reduces the impact of pressure changes within the interior of CVD Chamber 100 on External Cleaning Gas Source 150.

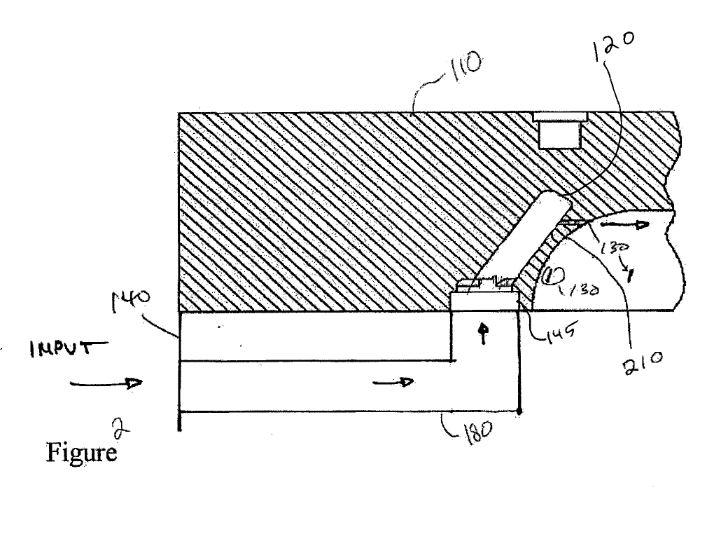

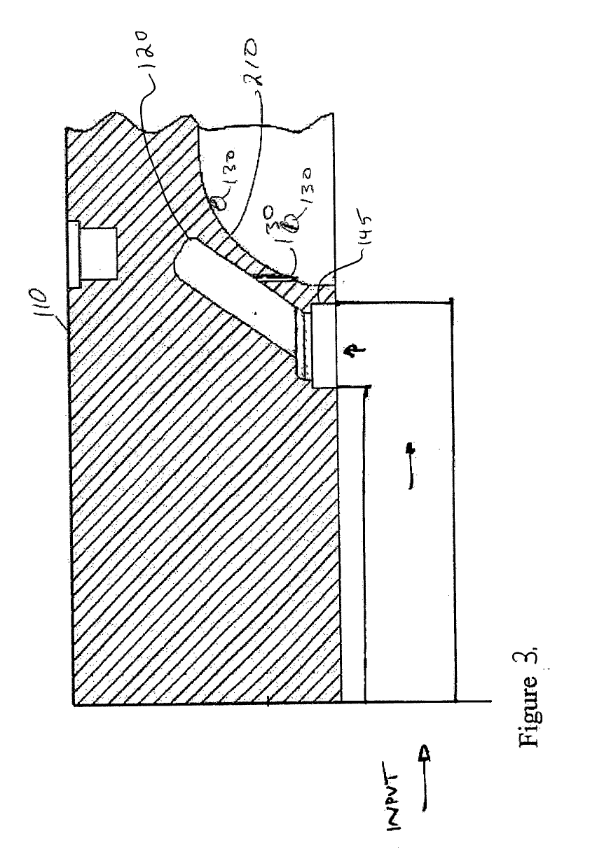

FIGS. 2 and 3 illustrate two possible orientations for Cleaning Gas Injection Ports 130. FIG. 2 illustrates an instance of Cleaning Gas Injection Ports 130 disposed roughly perpendicular to CVD Chamber Walls 140. In this orientation gasses passing into the interior of CVD Chamber 100 are directed toward the lower part of the interior. FIG. 3 illustrates an instance of Cleaning Gas Injection Ports 130 disposed roughly parallel to CVD Chamber Walls 140. In this orientation gasses passing through a Rim 210 into the interior of CVD Chamber 100 are directed toward the upper part of the interior. In some embodiments, different Cleaning Gas Injection Ports 130 are disposed at different angles relative to CVD Chamber Walls 140. Distributions of reactive cleaning gas concentrations within the interior of CVD Chamber 100 are responsive to the angles of Cleaning Gas Injection Ports 130, the diameter of Cleaning Gas Injection Ports 130, the spacing between Cleaning Gas Injection Ports 130, and/or the number of Cleaning Gas Injection ports at any particular angle. These parameters may be selected to create a desired distribution of reactive cleaning gas within the interior of CVD Chamber 100. The particular angles shown in FIGS. 2 and 3 are meant to be illustrative. Other angles are envisioned. Rim 210, including Cleaning Gas Injection Ports 130, may be concave as shown in FIGS. 2 and 3 or, alternatively, be flat or convex. In one embodiment, Rim 210 is approximately parallel to CVD Chamber Walls 140.

Alternative embodiments include a plurality of Cleaning Gas Distribution Channel 120. Each of the plurality being in fluid communication with a subset of the Cleaning Gas Injection Ports 130. For example, in one embodiment, a first instance of Cleaning Gas Distribution Channel 120 is disposed along a first half of the perimeter of CVD Chamber Lid 110 and a second instance of Cleaning Gas Distribution Channel 120 is disposed along a second half of the perimeter of CVD Chamber Lid 110. In another example, a first instance of Cleaning Gas Distribution Channel 120 is fluidly connected to a first subset of Cleaning Gas Injection Ports 130 disposed at a first angle (e.g., the angle illustrated in FIG. 2) and a second instance of Cleaning Gas Distribution Channel 120 is fluidly connected to a second subset of Cleaning Gas Injection Ports 130 disposed at a second angle relative to CVD Chamber Walls 140 (e.g., the angle illustrated in FIG. 3). Other embodiments include more than two instance of Cleaning Gas Distribution Channel 120.

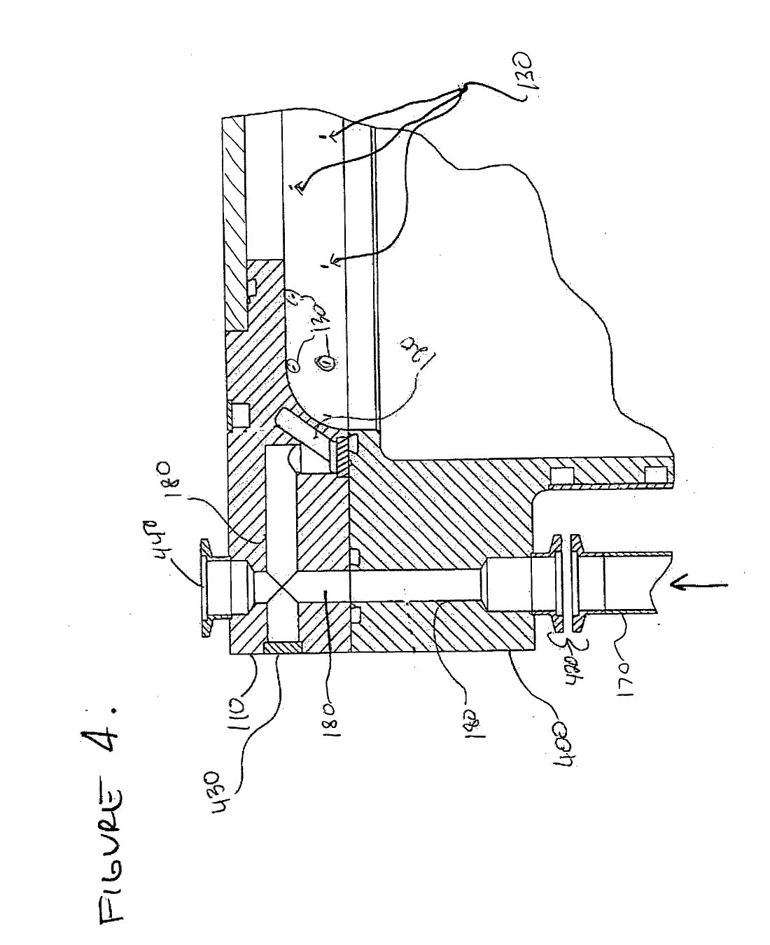

FIG. 4 illustrates an alternative embodiment of CVD Chamber 100 wherein CVD Chamber Walls 140 include a Chamber Collar 400 disposed between CVD Chamber Walls 140 and CVD Chamber Lid 110. Chamber Collar 400 may be joined to CVD Chamber Lid 100 using conventional techniques to provide a relatively airtight fit and sealed environment within CVD Chamber 100. Chamber Collar 400 includes Internal Plumbing 180 configured to deliver reactive cleaning gasses to Cleaning Gas Distribution Channel 120. In some embodiments, Chamber Collar 400 facilitates connection of External Plumbing 170 to Internal Plumbing 180. For example, as shown in FIG. 4, External Plumbing 170 may be connected to Internal Plumbing 180 via a Removable Connection 420. In alternative embodiments, External Plumbing 170 is removably connected to Internal Plumbing 180 at Point 430 or Point 440.

In a typical method of the invention reactive cleaning gas is generated in External Gas Source 150. For example, in some embodiments, reactive fluorine species (F, F₂, etc.) are generated using an RF plasma in External Gas Source 150. These plasma products are transported to Cleaning Gas Distribution Channel 120 using External Plumbing 170 and Internal Plumbing 180. Within Cleaning Gas Distribution Channel 120 the reactive cleaning gas circulates around the perimeter of CVD Chamber Lid 110. From Cleaning Gas Distribution Channel 120, the reactive cleaning gas passes into the interior of CVD Chamber 100 through the plurality of Cleaning Gas Injection Ports 130. In some embodiments a first subset of Cleaning Gas Injection Ports 130 are disposed to direct the reactive cleaning gas to the upper region of CVD Chamber 100 and a second subset of Cleaning Gas Injection Ports 130 are disposed to direct the reactive cleaning gas to the lower region of CVD Chamber 100. In one embodiment, a greater amount of reactive cleaning gas is directed to the upper region. This may be desirable because this region includes elements (e.g., CVD Chamber Walls 140 and Processing Gas Shower Head 160) that are at a lower temperature than elements in the lower region (e.g., a heater or elements near a heater). In this embodiment, a greater concentration of reactive cleaning gas is directed to the upper region to compensate for the temperature dependence of cleaning reaction rates.

When reactive cleaning gasses are first produced a significant change in molar volume may occur. For example, due to the generation of N₂, F and F₂ from NF₃. The volume of Cleaning Gas Distribution Channel 120 may serve as a buffer to this molar volume increase, such that the impact of the molar volume increase on External Cleaning Gas Source 150 is reduced.

The concepts of the invention herein may be also applied to other remote plasma and substrate processing cleaning systems including but not limited those described in the following United States Patents: U.S. Pat. No. 6,274,058 (entitled Remote Plasma Cleaning Method for Processing Chambers), U.S. Pat. No. 6,125,859 (entitled Method for Improved Cleaning of Substrate Processing Systems), U.S. Pat. No. 6,109,206 (entitled Remote Plasma Source for Chamber Cleaning) and U.S. Pat. No. 5,939,831 (entitled Methods and Apparatus for Pre-Stabilized Plasma Generation for Microwave Clean Applications), which are all incorporated by reference herein in their entirety. It shall be further understood that the invention may be also applied to atomic layer deposition (ALD) chamber cleaning.

We claim:

1. A chemical vapor deposition system comprising:
a cleaning gas source configured to generate a reactive cleaning gas; and
a chemical vapor deposition chamber including
a processing gas shower,
a cleaning gas distribution channel separate from the processing gas shower, and
a plurality of cleaning gas injection ports fluidly connected to the cleaning gas distribution channel and disposed to introduce the cleaning gas into an interior of the chemical vapor deposition chamber.

2. The chemical vapor deposition system of claim 1, wherein the cleaning gas distribution channel and plurality of cleaning gas injection ports are disposed within a lid of the chemical vapor deposition chamber.

3. The chemical vapor deposition system of claim 1, wherein the cleaning gas source is configured to generate reactive fluorine species.

4. The chemical vapor deposition system of claim 1, wherein the cleaning gas source is configured to generate a reactive cleaning gas for cleaning byproducts of WSiₓ film generation.

5. The chemical vapor deposition system of claim 1, wherein the plurality of cleaning gas injection ports include a first subset of the plurality of cleaning gas injection ports disposed at a first angle relative to side walls of the chemical vapor deposition chamber, and a second subset of the plurality of cleaning gas injection ports disposed at a second angle relative to the side walls.

6. The chemical vapor deposition system of claim 1, wherein the plurality of cleaning gas injection ports are distributed along an interior rim of a lid of the chemical vapor deposition chamber.

7. The chemical vapor deposition system of claim 1, further including internal plumbing configured to transport the reactive cleaning gas to the cleaning gas distribution channel, the internal plumbing being disposed within a wall of the chemical vapor deposition chamber.

8. The chemical vapor deposition system of claim 1, further including a plurality of channel openings configured for reactive cleaning gas to enter the cleaning gas distribution channel.

9. The chemical vapor deposition system of claim 1, further including a chamber collar configured to separate a lid of the chemical vapor deposition chamber from walls of the chemical vapor deposition chamber, the chamber collar including internal plumbing configured to supply reactive cleaning gas to the cleaning gas distribution channel.

10. The chemical vapor deposition system of claim 1, wherein the plurality of cleaning gas injection ports are configured to deliver a greater concentration of reactive cleaning gases to a cooler region of a chemical vapor deposition chamber than to a warmer region of the chemical vapor deposition chamber.

11. A chemical vapor deposition chamber lid comprising:
a cleaning gas distribution channel disposed within a perimeter of the chemical vapor deposition chamber lid and configured to circulate a reactive cleaning gas;
a plurality of cleaning gas injection ports configured to deliver the reactive cleaning gas from the cleaning gas distribution channel to an interior of a chemical vapor deposition chamber, the cleaning gas injection ports distributed around the chemical vapor deposition chamber lid and configured to deliver a greater concentration of the reactive cleaning gas to an upper region of the chemical vapor deposition chamber than to a lower region of the chemical vapor deposition chamber; and
internal plumbing configured to supply the reactive cleaning gas to the cleaning gas distribution channel.

12. The chemical vapor deposition chamber lid of claim 11, further including a lid section configured to support a processing gas shower, the processing gas shower being separate from the cleaning gas distribution channel.

13. The chemical vapor deposition chamber lid of claim 11, further including a processing gas shower separate from the internal plumbing.

14. The chemical vapor deposition chamber lid of claim 11, wherein the plurality of cleaning gas injection ports include a first subset of the plurality of cleaning gas injection ports disposed at a first angle relative to an edge of the chemical vapor deposition chamber lid, and a second subset of the plurality of cleaning gas injection ports disposed at a second angle relative to the edge.

15. The chemical vapor deposition chamber lid of claim 11, wherein the cleaning gas distribution channel has a cross-section ten or more times greater than a cross-section of one of the plurality of cleaning gas injection ports.

16. The chemical vapor deposition chamber lid of claim 11, wherein the plurality of cleaning gas injection ports are configured to deliver a greater concentration of reactive cleaning gases to a cooler region of a chemical vapor deposition chamber than to a warmer region of the chemical vapor deposition chamber.

17. A method of cleaning a chemical vapor deposition chamber, the method comprising:
generating a reactive cleaning gas;
transporting the reactive cleaning gas to a cleaning gas distribution channel, the cleaning gas distribution channel being separate from any processing gas shower head;
circulating the reactive cleaning gas around a perimeter of the lid;
passing the reactive cleaning gas into the interior of the chemical vapor deposition chamber using a plurality of cleaning gas injection ports disposed in the lid; and
generating a desired concentration gradient of the reactive cleaning gas in the chemical vapor deposition chamber.

18. The method of claim 17, wherein the reactive cleaning gas is passed into the interior of the chemical vapor deposition chamber at a variety of angles responsive to angles of the cleaning gas injection ports.

19. The method of claim 17, wherein the desired concentration gradient includes a greater concentration near cooler elements within the chemical vapor deposition chamber than near warmer elements.

20. The method of claim 17, wherein cleaning gas includes reactive fluorine species.

21. A chemical vapor deposition system comprising:
means for transporting a reactive cleaning gas to a cleaning gas distribution channel disposed in a lid of the chemical vapor deposition chamber;
means for circulating the reactive cleaning gas around a perimeter of the lid;
means for passing the reactive cleaning gas into the interior of the chemical vapor deposition chamber; and
means for generating a desired concentration gradient of the reactive cleaning gas in the chemical vapor deposition chamber, the desired concentration gradient including a greater concentration near cooler elements within the chemical vapor deposition chamber than near warmer elements.
